(19) United States
(12) Patent Application Publication
(10) Pub. No.: US 2007/0158754 A1
(43) Pub. Date: Jul. 12, 2007

(54) Semiconductor device and method of manufacturing the same

(75) Inventors: Mitsuru Soma, Saitama (JP); Hirotsugu Hata, Gunma (JP); Minoru Akaishi, Gunma (JP)

Correspondence Address: MORRISON & FOERSTER LLP, 1650 TYSONS BOULEVARD, SUITE 400, MCLEAN, VA, 22102, US

(73) Assignee: SANYO ELECTRIC CO., LTD., Osaka (JP)

(21) Appl. No.: 11/635,077

(22) Filed: Dec. 7, 2006

(30) Foreign Application Priority Data
Dec. 7, 2005 (JP) 2005-353836

(51) Int. Cl. H01L 29/76; H01L 29/94; H01L 31/00

(52) U.S. Cl. 257/370

(57) ABSTRACT

In a semiconductor device of the present invention, two epitaxial layers are formed on a P type single crystal silicon substrate. In the epitaxial layers, P type buried diffusion layers and P type diffusion layers are formed, which form isolation regions. In this event, the P type buried diffusion layers are formed by being expanded from a surface of a first epitaxial layer. By use of this structure, lateral expansion widths of the P type buried diffusion layers are reduced. Thus, the device size of an NPN transistor can be reduced.

### BACKGROUND OF THE INVENTION

Priority is claimed to Japanese Patent Application Number JP2005-353836 filed on Dec. 7, 2005, the disclosure of which is incorporated herein by reference in its entirety.

1. Field of the Invention

The present invention relates to a semiconductor device which realizes reduction in a device size while maintaining breakdown voltage characteristics, and a method of manufacturing the same.

2. Description of the Prior Art

As an embodiment of a conventional semiconductor device, a structure of the following NPN transistor 61 has been known. As shown in FIG. 9, an N type epitaxial layer 63 is formed on a P type semiconductor substrate 62. In the epitaxial layer 63, P type buried diffusion layers 64 and 65, which extend vertically (in a depth direction) from a surface of the substrate 62, and P type diffusion layers 66 and 67, which extend from a surface of the epitaxial layer 63, are formed. Moreover, the epitaxial layer 63 is divided into a plurality of element formation regions by isolation regions 68 and 69 which are formed by connecting the P type buried diffusion layers 64 and 65 with the P type diffusion layers 66 and 67, respectively. In one of the element formation regions, for example, the NPN transistor 61 is formed. The NPN transistor 61 is mainly formed of an N type buried diffusion layer 70 and an N type diffusion layer 71, which are used as a collector region, a P type diffusion layer 72 used as a base region and an N type diffusion layer 73 used as an emitter region. This technology is described for instance in Japanese Patent Application Publication No. Hei 9 (1997)-283646 (Pages 3, 4 and 6, FIGS. 1 and 5 to 7).

As described above, in the conventional semiconductor device, a thickness of the epitaxial layer 63 is determined by taking account of a breakdown voltage of the NPN transistor 61 and the like. For example, in a case where a power semiconductor element and a control semiconductor element are monolithically formed on the same semiconductor substrate 62, the thickness of the epitaxial layer 63 is determined according to breakdown voltage characteristics of the power semiconductor element. Moreover, the P type buried diffusion layers 64 and 65, which form the isolation regions 68 and 69, respectively, expand upward from the surface of the substrate 62 toward the epitaxial layer 63. Meanwhile, the P type diffusion layers 66 and 67, which form the isolation regions 68 and 69, respectively, expand downward from the surface of the epitaxial layer 63. By use of this structure, lateral expansion widths W4 and W5 respectively of the P type buried diffusion layers 64 and 65 are also increased according to the upward expansion widths thereof. In order to realize a desired breakdown voltage of the NPN transistor 61, a distance L2 between the P type diffusion layer 72 and the isolation region 68 is required to be a certain distance or more. Thus, there is a problem that the increase in the lateral expansion widths W4 and W5 respectively of the P type buried diffusion layers 64 and 65 makes it difficult to reduce a device size of the NPN transistor 61.

Moreover, in a conventional method of manufacturing a semiconductor device, the isolation regions 68 and 69 are formed by connecting the P type buried diffusion layers 64 and 65 with the P type diffusion layers 66 and 67, respectively. To this end, a thermal diffusion step of expanding the P type buried diffusion layers 64 and 65 is performed after the epitaxial layer 63 is formed. Furthermore, since the P type diffusion layers 66 and 67 are used in a dedicated ion implantation step of forming the isolation regions 68 and 69, respectively, a dedicated thermal diffusion step of expanding the P type diffusion layers 66 and 67 is required. By use of this manufacturing method, particularly, the lateral expansion widths W4 and W5 respectively of the P type buried diffusion layers 64 and 65 are increased. As a result, there is a problem that it is difficult to reduce the device size of the NPN transistor 61.

Moreover, in the conventional method of manufacturing a semiconductor device, after the P type diffusion layers 66 and 67, which form the isolation regions 68 and 69, respectively, are formed from the surface of the epitaxial layer 63, LOCOS (Local Oxidation of Silicon) oxide films 74 and 75 are formed by thermal oxidation. When an ion implantation step using boron (B), for example, as P type impurities is performed to form the P type diffusion layers 66 and 67, formation regions of the P type diffusion layers 66 and 67 may be damaged by the ion implantation. In this case, there is a problem that a subsequent thermal oxidation step of forming the LOCOS oxide films 74 and 75 makes it easy for crystal defects to be formed from the damaged regions in the formation regions of the P type diffusion layers 66 and 67, respectively.

### SUMMARY OF THE INVENTION

The present invention has been made in consideration for the foregoing circumstances. A semiconductor device of the present invention includes a semiconductor substrate of one conductivity type, a first epitaxial layer of an opposite conductivity type formed on the semiconductor substrate, a second epitaxial layer of the opposite conductivity type formed on the first epitaxial layer, a isolation region of the one conductivity type which divides the first and second epitaxial layers into a plurality of element formation regions, a buried diffusion layer of the opposite conductivity type formed so as to extend in the semiconductor substrate and the first epitaxial layer, a buried diffusion layer of the one conductivity type which forms the isolation region, which is formed from a surface of the first epitaxial layer, and which is connected to the semiconductor substrate, a first diffusion layer of the one conductivity type which forms the isolation region, which is formed from a surface of the second epitaxial layer, and which is connected to the buried diffusion layer of the one conductivity type, a first diffusion layer of the opposite conductivity type which is formed in the second epitaxial layer, and which is used as a collector region, a second diffusion layer of the one conductivity type which is formed in the second epitaxial layer, and which is used as a base region, and a second diffusion layer of the opposite conductivity type which is formed so as to overlap with the second diffusion layer of the one conductivity type, and which is used as an emitter region. In the present invention, therefore, a lateral expansion of the buried diffusion layer of the one conductivity type, which forms the isolation region, can be suppressed. Thus, a device size can be reduced.

A method of manufacturing a semiconductor device according to the present invention includes the steps of preparing a semiconductor substrate of one conductivity type, forming a buried diffusion layer of an opposite conductivity type in the semiconductor substrate, and thereafter forming a first epitaxial layer of the opposite conductivity type on the semiconductor substrate, implanting ions of impurities of the one conductivity type in a desired region of the first epitaxial layer, thereafter forming a second epitaxial layer of the opposite conductivity type on the first epitaxial layer, and forming a buried diffusion layer of the one conductivity type so as to extend in the first and second epitaxial layers, forming a first diffusion layer of the one conductivity type, which is connected to the buried diffusion layer of the one conductivity type, in the second epitaxial layer, forming a first diffusion layer of the opposite conductivity type, which is used as a collector region, in the second epitaxial layer, forming a second diffusion layer of the one conductivity type, which is used as a base region, in the second epitaxial layer, and forming a second diffusion layer of the opposite conductivity type, which is used as an emitter region, in the second diffusion layer of the one conductivity type. In the present invention, therefore, the two layers of the first and second epitaxial layers are formed on the semiconductor substrate. By forming the buried diffusion layer of the one conductivity type from a surface of the first epitaxial layers, a lateral expansion thereof can be suppressed.

Moreover, the method of manufacturing a semiconductor device according to the present invention includes an ion implantation step for forming the first diffusion layer of the one conductivity type is performed without performing a thermal diffusion step for expanding the buried diffusion layer of the one conductivity type after the second epitaxial layer is formed. In the present invention, therefore, by controlling a thickness of the first epitaxial layer so that the dedicated thermal diffusion step for the buried diffusion layer of the one conductivity type can be omitted, lateral expansion of the buried diffusion layer of the one conductivity type can be suppressed.

Moreover, the method of manufacturing a semiconductor device according to the present invention includes, after a LOCOS oxide film is formed in the second epitaxial layer, ions of impurities of the one conductivity type for forming the first diffusion layer of the one conductivity type are implanted from a surface of the LOCOS oxide film. In the present invention, therefore, it is possible to reduce crystal defects in a formation region of the first diffusion layer of the one conductivity type.

Moreover, a method of manufacturing a semiconductor device according to the present invention includes the steps of preparing a semiconductor substrate of one conductivity type, forming a first buried diffusion layer of an opposite conductivity type and a second buried diffusion layer of the opposite conductivity type in the semiconductor substrate, and thereafter forming a first epitaxial layer of the opposite conductivity type on the semiconductor substrate, implanting ions of impurities of the one conductivity type in a desired region of the first epitaxial layer, thereafter forming a second epitaxial layer of the opposite conductivity type on the first epitaxial layer, and forming a buried diffusion layer of the one conductivity type so as to extend in the first and second epitaxial layers, forming a first diffusion layer of the one conductivity type, which is connected to the buried diffusion layer of the one conductivity type, and a second diffusion layer of the one conductivity type, which is used as a back gate region, in the second epitaxial layer, forming a third diffusion layer of the one conductivity type, which is used as a base region, in the second epitaxial layer, forming an first diffusion layer of the opposite conductivity type, which is used as a collector region, in the second epitaxial layer, forming an second diffusion layer of the opposite conductivity type, which is used as an emitter region, in the third diffusion layer of the one conductivity type, and forming an third diffusion layer of the opposite conductivity type, which is used as a source region, and an fourth diffusion layer of the opposite conductivity type, which is used as a drain region, in the second diffusion layer of the one conductivity type. In the present invention, therefore, even in a case where a plurality of elements are monolithically formed on the substrate, by forming the buried diffusion layer of the one conductivity type from a surface of the first epitaxial layer, the lateral expansion can be suppressed.

Moreover, the method of manufacturing a semiconductor device according to the present invention includes the first diffusion layer of the one conductivity type and the second diffusion layer of the one conductivity type are formed by the same ion implantation step. Therefore, in the present invention, the ion implantation step for forming the first diffusion layer of the one conductivity type which forms a isolation region and an ion implantation step for forming other elements are a common step. By use of this manufacturing method, the thermal diffusion step can be omitted, and the lateral expansion of the buried diffusion layer of the one conductivity type can be suppressed.

### BRIEF DESCRIPTION OF THE DRAWINGS

FIG. 1 is a cross-sectional view illustrating a semiconductor device according to an embodiment of the present invention.

FIG. 2 is a graph illustrating breakdown voltage characteristics of a semiconductor device according to the embodiment of the present invention.

FIG. 3 is a cross-sectional view illustrating a method of manufacturing a semiconductor device according to the embodiment of the present invention.

FIG. 4 is a cross-sectional view illustrating the method of manufacturing a semiconductor device according to the embodiment of the present invention.

FIG. 5 is a cross-sectional view illustrating the method of manufacturing a semiconductor device according to the embodiment of the present invention.

FIG. 6 is a cross-sectional view illustrating the method of manufacturing a semiconductor device according to the embodiment of the present invention.

FIG. 7 is a cross-sectional view illustrating the method of manufacturing a semiconductor device according to the embodiment of the present invention.

FIG. 8 is a cross-sectional view illustrating the method of manufacturing a semiconductor device according to the embodiment of the present invention.

FIG. 9 is a cross-sectional view illustrating a semiconductor device according to a conventional embodiment.

### DESCRIPTION OF THE PREFERRED EMBODIMENTS

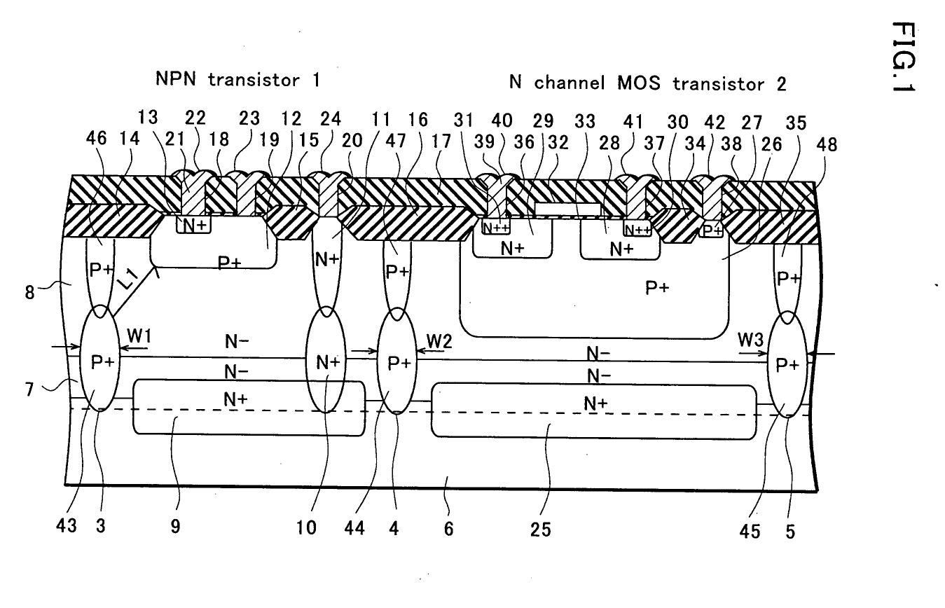

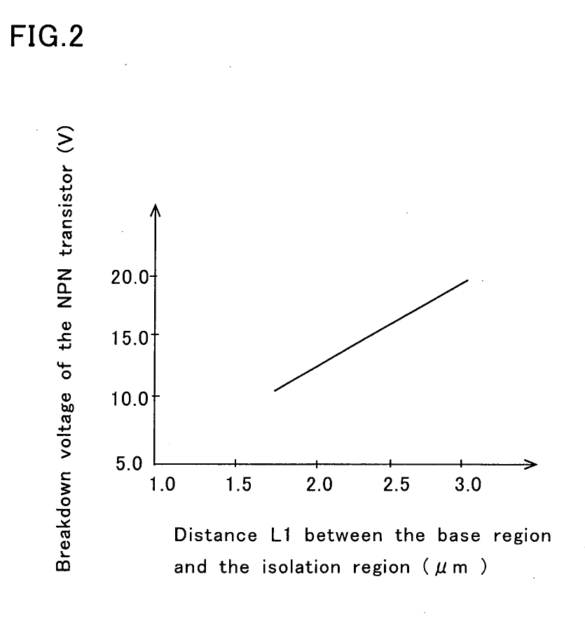

With reference to FIGS. 1 and 2, a semiconductor device according to an embodiment of the present invention will be described in detail below. FIG. 1 is a cross-sectional view illustrating the semiconductor device according to this embodiment. FIG. 2 is a graph illustrating breakdown voltage characteristics of the semiconductor device according to this embodiment.

As shown in FIG. 1, an NPN transistor 1 is formed in one of element formation regions divided by isolation regions 3, 4 and 5, and an N channel MOS (Metal Oxide Semiconductor) transistor 2 is formed in other element formation regions. Note that, although not shown in FIG. 1, a P channel MOS transistor, a PNP transistor and the like are formed in the other element formation regions.

As shown in FIG. 1, the NPN transistor 1 is mainly formed of a P type single crystal silicon substrate 6, N type epitaxial layers 7 and 8, N type buried diffusion layers 9 and 10 used as a collector region, an N type diffusion layer 11 used as the collector region, a P type diffusion layer 12 used as a base region, and an N type diffusion layer 13 used as an emitter region.

The N type epitaxial layers 7 and 8 are formed on the P type single crystal silicon substrate 6. Specifically, on the substrate 6, the two epitaxial layers 7 and 8 are stacked. The first epitaxial layer 7 is formed so as to have a thickness of, for example, about 0.6 to 1.0 (μm). Meanwhile, the second epitaxial layer 8 is formed so as to have a thickness of, for example, about 1.0 to 1.5 (μm).

The N type buried diffusion layer 9 is formed so as to extend in the substrate 6 and the first epitaxial layer 7. Moreover, the N type buried diffusion layer 10 is formed so as to extend in the first epitaxial layer 7 and the second epitaxial layer 8. Furthermore, the N type buried diffusion layer 10 is connected to the N type buried diffusion layer 9.

The N type diffusion layer 11 is formed in the second epitaxial layer 8. The N type diffusion layer 11 is connected to the N type buried diffusion layer 10. Moreover, the N type buried diffusion layers 9 and 10 and the N type diffusion layer 11 are used as the collector region of the NPN transistor 1.

The P type diffusion layer 12 is formed in the second epitaxial layer 8 and is used as the base region.

The N type diffusion layer 13 is formed in the P type diffusion layer 12 and is used as the emitter region.

LOCOS oxide films 14, 15 and 16 are formed in the second epitaxial layer 8. Each of the LOCOS oxide films 14, 15 and 16 has a thickness of, for example, about 3000 to 10000 Å in its flat portion. Below the LOCOS oxide films 14, 15 and 16, the P type isolation regions 3 and 4 are formed, respectively.

An insulating layer 17 is formed on an upper surface of the second epitaxial layer 8. The insulating layer 17 is formed of an NSG (Nondoped Silicate Glass) film, a BPSG (Boron Phospho Silicate Glass) film or the like. By use of a known photolithography technology, contact holes 18, 19 and 20 are formed in the insulating layer 17 by dry etching using, for example, CHF₃ or CF₄ gas.

In the contact holes 18, 19 and 20, aluminum alloy films 21 made of, for example, an Al—Si film, an Al—Si—Cu film, an Al—Cu film or the like are selectively formed. Thus, an emitter electrode 22, a base electrode 23 and a collector electrode 24 are formed.

Meanwhile, the N channel MOS transistor 2 is mainly formed of the P type single crystal silicon substrate 6, the N type epitaxial layers 7 and 8, an N type buried diffusion layer 25, P type diffusion layers 26 and 27 used as a back gate region, N type diffusion layers 28 and 30 used as a source region, N type diffusion layers 29 and 31 used as a drain region, and a gate electrode 32.

The N type epitaxial layers 7 and 8 are formed on the P type single crystal silicon substrate 6.

The N type buried diffusion layer 25 is formed across the substrate 6 and the first epitaxial layer 7.

The P type diffusion layer 26 is formed in the second epitaxial layer 8 and is used as the back gate region. The P type diffusion layer 27 is formed with overlapping the P type diffusion layer 26. The P type diffusion layer 27 is used as a back gate draw-out region.

The N type diffusion layers 28 and 29 are formed in the P type diffusion layer 26. The N type diffusion layer 28 is used as the source region. The N type diffusion layer 29 is used as the drain region. The N type diffusion layer 30 is formed in the N type diffusion layer 28, and the N type diffusion layer 31 is formed in the N type diffusion layer 29. By use of this structure, the drain region is formed to have a DDD (Double Diffused Drain) structure. Moreover, the P type diffusion layer 26 positioned between the N type diffusion layers 28 and 29 is used as a channel region. On the upper surface of the epitaxial layer 8 above the channel region, a gate oxide film 33 is formed.

The gate electrode 32 is formed on an upper surface of the gate oxide film 33. The gate electrode 32 is formed of, for example, a polysilicon film and a tungsten silicide film so as to have a desired thickness. Although not shown in FIG. 1, a silicon oxide film is formed on an upper surface of the tungsten silicide film.

The LOCOS oxide film 16 and LOCOS oxide films 34 and 35 are formed in the second epitaxial layer 8. Although not shown in FIG. 1, N type diffusion layers may be formed below the LOCOS oxide films 16 and 35 between the P type diffusion layer 26 and the P type isolation regions 4 and 5. In this case, the N type diffusion layers can prevent short-circuits of the P type diffusion layer 26 and the P type isolation regions 4 and 5 due to inversion of the surface of the epitaxial layer 8.

The insulating layer 17 is formed on an upper surface of the second epitaxial layer 8. By use of the known photolithography technology, contact holes 36, 37 and 38 are formed in the insulating layer 17 by dry etching using, for example, CHF₃ or CF₄ gas.

In the contact holes 36, 37 and 38, aluminum alloy films 39 made of, for example, an Al—Si film, an Al—Si—Cu film, an Al—Cu film or the like are selectively formed. Thus, a drain electrode 40, a source electrode 41 and a back gate electrode 42 are formed.

In this embodiment, the isolation regions 3, 4 and 5 are formed by connecting P type buried diffusion layers 43, 44 and 45, which are diffused from the surface of the first epitaxial layer 7, to P type diffusion layers 46, 47 and 48, respectively, which are diffused from the surface of the second epitaxial layer 8. Moreover, the P type buried diffusion layers 43, 44 and 45 are connected to the substrate 6.

Here, although varying depending on breakdown voltage characteristics of the NPN transistor 1, description will be given of the case where, for example, thicknesses of the epitaxial layers 7 and 8 are about 2.1 (μm) in total. The thickness of the first epitaxial layer 7 is set to be about 0.6 (μm), and the thickness of the second epitaxial layer 8 is set to be about 1.5 (μm). In this case, the P type buried diffusion layers 43, 44 and 45 expand toward the epitaxial layer 7 side by about 0.6 (μm). Moreover, lateral expansion widths W1, W2 and W3 respectively of the P type buried diffusion layers 43, 44 and 45 are set to be about 0.48 (μm). This is because, although varying depending on a crystalline state of the epitaxial layer and the like, the lateral expansion width of the diffusion layer is about 0.8 times an upward expansion width (or a downward expansion width) of the diffusion layer.

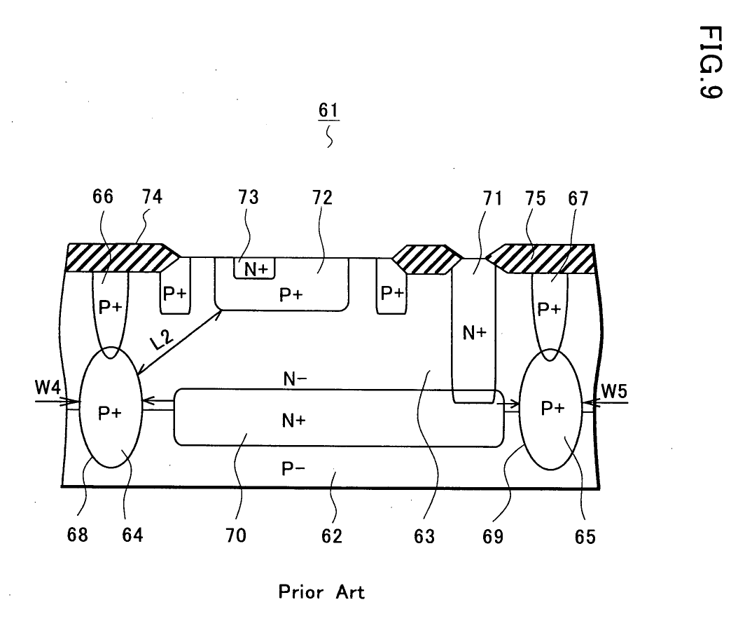

Meanwhile, as described with reference to FIG. 9, considered is a case where one epitaxial layer 63 having a thickness of 2.1 (μm) is deposited on a substrate 62 in a conventional structure. In this case, in order to expand P type buried diffusion layers 64 and 65 from a surface of the substrate 62, the P type buried diffusion layers 64 and 65 are allowed to expand toward the epitaxial layer 63 by about 1.2 (μm). Accordingly, lateral expansion widths of the P type buried diffusion layers 64 and 65 are set to be about 0.96 (μm) as in the case of the foregoing case.

Specifically, by expanding the P type buried diffusion layers 43, 44 and 45 vertically (in a depth direction) from the surface of the first epitaxial layer 7, the diffusion widths thereof are suppressed. Thus, the lateral expansion widths W1, W2 and W3 can be reduced. Moreover, as in the case of the conventional structure, in a distance L1 between the P type diffusion layer 12 and the P type isolation region 3, a certain width is required according to the breakdown voltage characteristics of the NPN transistor 1. However, by reducing the lateral expansion widths W1, W2 and W3 respectively of the P type buried diffusion layers 43, 44 and 45, a device size of the NPN transistor 1 can be reduced. Note that, the distance L1 is set to be a distance between the P type diffusion layer 12 and the P type isolation region 3, which affects the breakdown voltage characteristics of the NPN transistor 1.

In FIG. 2, a horizontal axis indicates the distance L1 between the base region (the P type diffusion layer 12) and the isolation region 3, and a vertical axis indicates the breakdown voltage characteristics of the NPN transistor 1. As shown in FIG. 2, the longer the distance L1, the higher the breakdown voltage value the NPN transistor 1 gets. Specifically, as the distance L1 is extended, the breakdown voltage characteristics of the NPN transistor 1 are improved. However, in the meantime, the device size of the NPN transistor 1 is increased. Thus, the distance L1 is designed also in consideration of the device size of the NPN transistor 1.

Note that, as shown in FIG. 1, the dotted line indicates a boundary region between the substrate 6 and the first epitaxial layer 7. As described above, the substrate 6 contains P type impurities, and P type diffusion regions expanding upward from the substrate 6 are formed in the epitaxial layer 7. By use of this structure, the lateral expansion widths W1, W2 and W3 respectively of the P type buried diffusion layers 43, 44 and 45 are further suppressed by connecting the P type buried diffusion layers 43, 44 and 45 to the P type diffusion regions. Accordingly, the device size of the NPN transistor 1 is also further reduced.

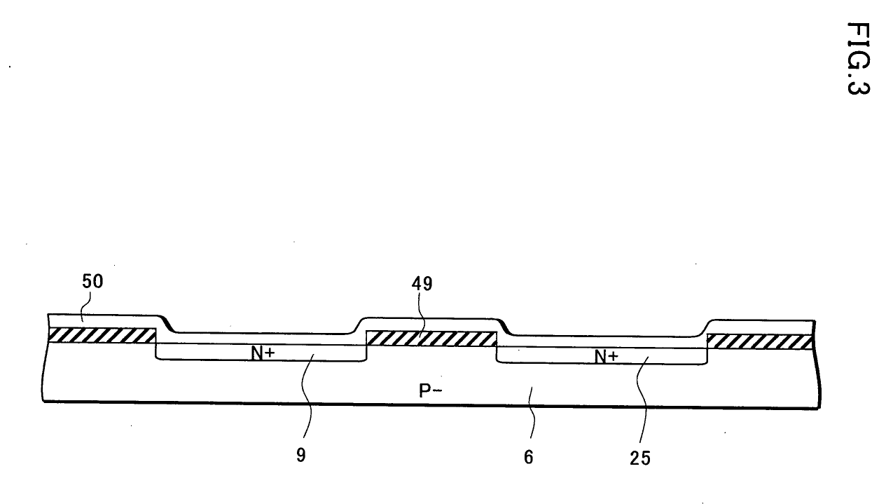

Next, with reference to FIGS. 3 to 8, detailed description will be given of a method of manufacturing a semiconductor device according to an embodiment of the present invention. FIGS. 3 to 8 are cross-sectional views illustrating the method of manufacturing a semiconductor device according to this embodiment.

First, as shown in FIG. 3, a P type single crystal silicon substrate 6 is prepared. A silicon oxide film 49 is formed on the substrate 6, and the silicon oxide film 49 is selectively removed so as to form openings on formation regions of N type buried diffusion layers 9 and 25. Thereafter, by using the silicon oxide film 49 as a mask, a liquid source 50 containing N type impurities, for example, antimony (Sb) is applied onto a surface of the substrate 6 by use of a spin-coating method. Subsequently, after the antimony (Sb) is thermally diffused to form the N type buried diffusion layers 9 and 25, the silicon oxide film 49 and the liquid source 50 are removed.

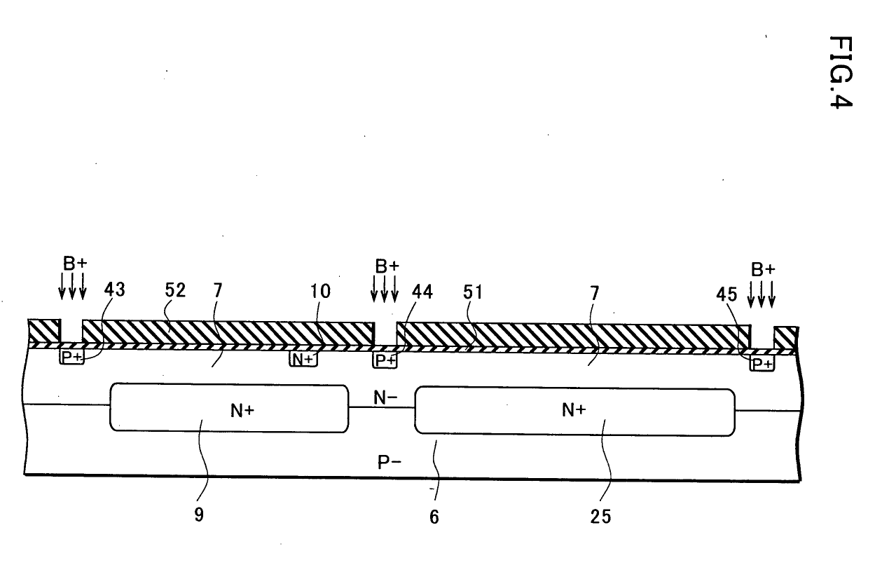

Next, as shown in FIG. 4, the substrate 6 is placed on a susceptor of a vapor phase epitaxial growth apparatus, and an N type epitaxial layer 7 is formed on the substrate 6. In this event, the epitaxial layer 7 is formed so as to have a thickness of about 0.6 to 1.0 (μm). The N type buried diffusion layers 9 and 25 are expanded by heat treatment of thermal diffusion in the step of forming the epitaxial layer 7. Thereafter, a silicon oxide film 51 is formed on the epitaxial layer 7, and a photoresist (not shown) having an opening on a formation region of an N type buried diffusion layer 10 to be described later is used as a mask to form the N type buried diffusion layer 10 by use of, for example, an ion implantation method. Note that, the step of forming the N type buried diffusion layer 10 may be omitted.

Next, a photoresist 52 is formed on the silicon oxide film 51. Thereafter, by use of a known photolithography technology, openings are formed in the photoresist 52 on regions where P type buried diffusion layers 43, 44 and 45 are formed. Subsequently, ions of P type impurities, for example, boron (B) are implanted from a surface of the epitaxial layer 7 at an accelerating voltage of 180 to 200 (keV) and a dose of 1.0×10¹² to 1.0×10¹⁴ (/cm²). Note that, in this embodiment, impurity concentration peaks of the ion implanted P type buried diffusion layers 43, 44 and 45 are positioned at a depth of about 0.2 to 0.3 (μm) from the surface of the epitaxial layer 7. Furthermore, impurity concentration peak positions by the ion implantation can be arbitrarily controlled by arbitrarily changing the accelerating voltage of the ion implantation. Based on the peak positions, formation positions of the P type buried diffusion layers 43, 44 and 45 can be controlled. Subsequently, the silicon oxide film 51 and the photoresist 52 are removed without expanding the P type buried diffusion layers 43, 44 and 45 by the thermal diffusion.

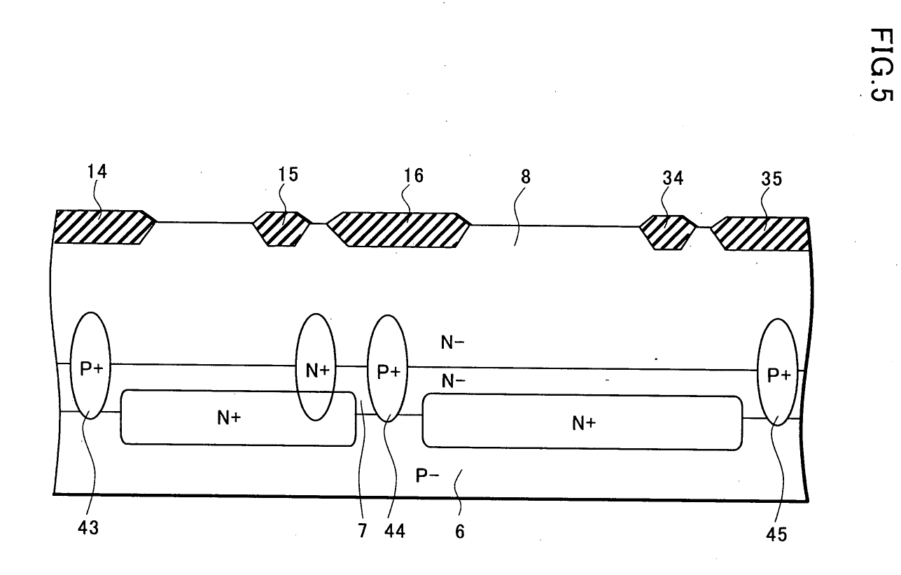

Next, as shown in FIG. 5, the substrate 6 is placed on the susceptor of the vapor phase epitaxial growth apparatus, and an N type epitaxial layer 8 is formed on the epitaxial layer 7. In this event, the epitaxial layer 8 is formed so as to have a thickness of about 1.0 to 1.5 (μm). Moreover, thicknesses of the epitaxial layers 7 and 8 are set to be, for example, about 2.0 to 2.1 (μm) in total. The P type buried diffusion layers 43, 44 and 45 are expanded by heat treatment of thermal diffusion in the step of forming the epitaxial layer 8. Thereafter, LOCOS oxide films 14, 15 and 16, 34 and 35 are formed in desired regions of the epitaxial layer 8.

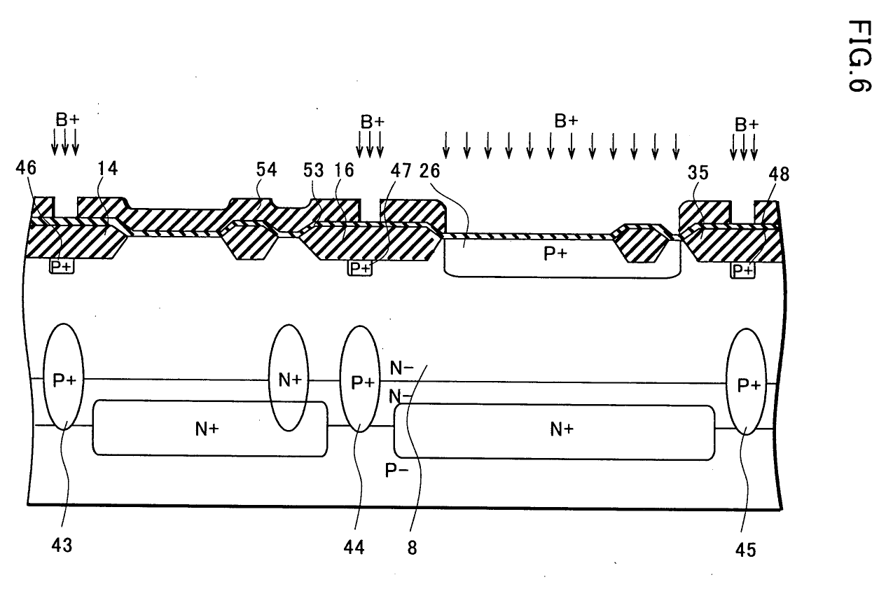

Next, as shown in FIG. 6, a silicon oxide film 53 is deposited to have a thickness of, for example, about 450 (Å) the epitaxial layer 8. Thereafter, a photoresist 54 is formed on the silicon oxide film 53. Subsequently, by use of the known photolithography technology, openings are formed in the photoresist 54 on regions where P type diffusion layers 26, 46, 47 and 48 are formed. Thereafter, ions of P type impurities, for example, boron (B) are implanted from a surface of the epitaxial layer 8 at an accelerating voltage of 180 to 200 (keV) and a dose of 1.0×10¹² to 1.0×10¹⁴ (/cm²). Subsequently, the photoresist 54 is removed, and the P type diffusion layers 26, 46, 47 and 48 are formed by thermal diffusion.

In this event, after the epitaxial layer 8 is formed, the P type diffusion layers 26, 46, 47 and 48 are formed without performing the thermal diffusion step for expanding the P type buried diffusion layers 43, 44 and 45. This manufacturing method makes it possible to omit the thermal diffusion step for expanding the P type buried diffusion layers 43, 44 and 45, which has been required in the conventional manufacturing method, by controlling the thickness of the epitaxial layer 7.

Furthermore, the ion implantation step for forming the P type diffusion layers 46 to 48, which form isolation regions 3, 4 and 5, respectively, and the ion implantation step for forming the P type diffusion layer 26 that is a back gate region of an N channel MOS transistor 2 are set to be a common step. Thus, it is possible to omit the thermal diffusion step for separately diffusing the P type diffusion layers 46 to 48, which has been required in the conventional manufacturing method.

By use of the manufacturing method, compared with the conventional manufacturing method, the two thermal diffusion steps can be omitted for the P type buried diffusion layers 43, 44 and 45. Moreover, lateral expansion widths W1, W2 and W3 respectively (see FIG. 1) of the P type buried diffusion layers 43, 44 and 45 can be reduced, and the device size of an NPN transistor 1 can be reduced.

Moreover, after the LOCOS oxide films 14, 16 and 35 are formed, ions of boron (B) are implanted from above the LOCOS oxide films 14, 16 and 35. This manufacturing method can prevent formation of crystal defects due to heat during formation of the LOCOS oxide films 14, 16 and 35 from the surface of the epitaxial layer 8 damaged by implanting the ions of boron (B) having a relatively large molecular level.

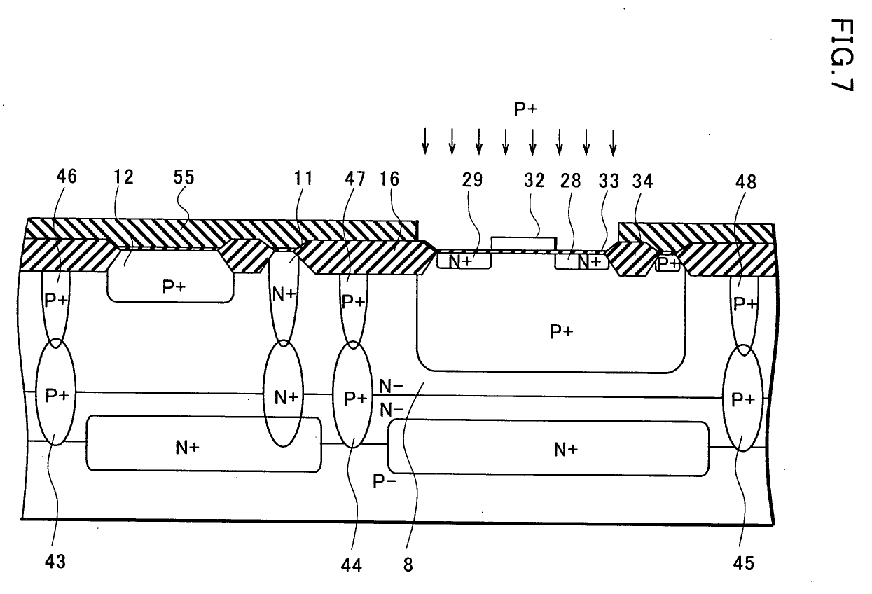

Next, as shown in FIG. 7, after a P type diffusion layer 12 and an N type diffusion layer 11 are sequentially formed in the epitaxial layer 8, a silicon oxide film to be used as a gate oxide film 33 is formed on the epitaxial layer 8. Thereafter, a polysilicon film and a tungsten silicide film, for example, are sequentially formed on the gate oxide film 33 to form a gate electrode 32 by use of the known photolithography technology. Subsequently, a photoresist 55 is formed on the silicon oxide film used as the gate oxide film 33. By use of the known photolithography technology, openings are formed in the photoresist 55 on regions where N type diffusion layers 28 and 29 are to be formed. Subsequently, ions of N type impurities, for example, phosphorus (P) are implanted from the surface of the epitaxial layer 8 to form the N type diffusion layers 28 and 29. In this event, by utilizing the LOCOS oxide films 16 and 34 and the gate electrode 32 as a mask, the N type diffusion layers 28 and 29 can be formed with good positional accuracy. Thereafter, the photoresist 55 is removed.

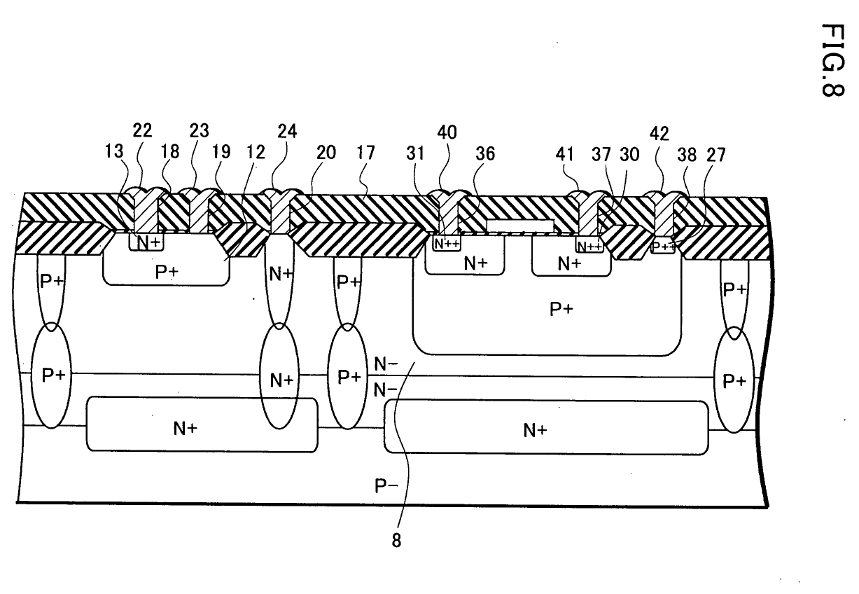

Next, as shown in FIG. 8, by use of the known photolithography technology, N type diffusion layers 13, 30 and 31 are formed after a P type diffusion layer 27 is formed.

Thereafter, on the epitaxial layer 8, an NSG film, a BPSG film or the like, for example, is deposited as an insulating layer 17. Subsequently, by use of the known photolithography technology, contact holes 18, 19 and 20 and 36, 37 and 38 are formed in the insulating layer 17 by dry etching using, for example, CHF₃ or CF₄ gas. In the contact holes 18, 19 and 20 and 36, 37 and 38, aluminum alloy films made of, for example, an Al—Si film, an Al—Si—Cu film, an Al—Cu film or the like are selectively formed. Thus, an emitter electrode 22, a base electrode 23, a collector electrode 24, a drain electrode 40, a source electrode 41 and a back gate electrode 42 are formed.

Note that, in this embodiment, the description has been given of the case where the isolation regions 3, 4 and 5 are formed by expanding the P type buried diffusion layers 43, 44 and 45 respectively from the surface of the first epitaxial layer 7 and by expanding the P type diffusion layers 46 to 48 respectively from the surface of the second epitaxial layer 8. However, the present invention is not limited to this case. For example, the present invention may be applied to a case where a P type buried diffusion layer is further formed from the surface of the substrate 6 and the isolation regions 3, 4 and 5 are formed of the P type buried diffusion layers 43, 44 and 45 and the P type diffusion layers 46 to 48, respectively. In this case, the lateral expansion widths W1, W2 and W3 of the P type buried diffusion layers 43, 44 and 45, respectively, can be further reduced.

Moreover, in this embodiment, the description has been given of the case where the N type buried diffusion layers 9 and 25 are formed so as to extend in the substrate 6 and the first epitaxial layer 7. However, the present invention is not limited to this case. For example, the present invention may be applied to a case where an N type buried diffusion layer is formed so as to extend in the first and second epitaxial layers 7 and 8 and is connected to the N type buried diffusion layer 9 in a formation region of the NPN transistor 1. In this case, a collector resistance of the NPN transistor 1 can be reduced. Besides, various changes can be made without departing from the scope of the present invention.

In the present invention, the two epitaxial layers are formed on the substrate. The buried diffusion layer, which forms the isolation region, expands from the surface of the first epitaxial layer. By use of this structure, a lateral expansion width of the buried diffusion layer is reduced. Thus, a device size can be reduced.

Moreover, in the embodiment of the present invention, the buried diffusion layer, which forms the isolation region, is formed from the surface of the first epitaxial layer, and the method includes no dedicated diffusion step for expanding the buried diffusion layer. By use of this manufacturing method, the lateral expansion width of the buried diffusion layer is reduced. Thus, the device size can be reduced.

Moreover, in the embodiment of the present invention, the step of forming the diffusion layer which forms the isolation region is set to be a common step. By use of this manufacturing method, a dedicated thermal diffusion step for forming the diffusion layer which forms the isolation region is omitted. Moreover, the lateral expansion width of the buried diffusion layer is reduced. Thus, the device size can be reduced.

Moreover, in the embodiment of the present invention, after the LOCOS oxide film is formed, the diffusion layer which forms the isolation region is formed. This manufacturing method makes it possible to reduce crystal defects formed on a surface of a formation region of the diffusion layer and in a region adjacent thereto.

What is claimed is:

1. A semiconductor device comprising:
a semiconductor substrate of a first general conductivity type;
a first epitaxial layer of a second general conductivity type disposed on the semiconductor substrate;
a second epitaxial layer of the second general conductivity type disposed on the first epitaxial layer;
a buried diffusion layer of the second general conductivity type formed so as to extend in the semiconductor substrate and the first epitaxial layer in a horizontal direction;
a buried diffusion layer of the first general conductivity type formed so as to extend in the semiconductor substrate and the first and second epitaxial layers in a vertical direction;
a first diffusion layer of the first general conductivity type formed so as to extend in the second epitaxial layer in the vertical direction;
a first diffusion layer of the second general conductivity type formed in the second epitaxial layer so as to operate as a collector region;
a second diffusion layer of the first general conductivity type formed in the second epitaxial layer so as to operate as a base region; and
a second diffusion layer of the second general conductivity type formed in the second diffusion layer of the first general conductivity type so as to operate as an emitter region,
wherein the buried diffusion layer of the first general conductivity type is in contact with the first diffusion layer of the first general conductivity type so as to form an isolation region separating a portion of the first and second epitaxial layers from other portion of the first and second epitaxial layers.

2. A method of manufacturing a semiconductor device, comprising:
providing a semiconductor substrate of a first general conductivity type;
forming a buried diffusion layer of a second general conductivity type in the semiconductor substrate;
forming a first epitaxial layer of the second general conductivity type on the semiconductor substrate having the buried diffusion layer formed therein;
implanting impurities of the first general conductivity type into a portion of the first epitaxial layer;
forming a second epitaxial layer of the second general conductivity type on the first epitaxial layer so as to form a buried diffusion layer of the first general conductivity type extending in the first and second epitaxial layers;
forming a first diffusion layer of the first general conductivity type in the second epitaxial layer so that the first diffusion layer of the first general conductivity type is in contact with the buried diffusion layer of the first general conductivity type;
forming a first diffusion layer of the second general conductivity type in the second epitaxial layer so as to operate as a collector region;
forming a second diffusion layer of the first general conductivity type in the second epitaxial layer so as to operate as a base region; and
forming a second diffusion layer of the second general conductivity type in the second diffusion layer of the first general conductivity type so as to operate as an emitter region.

3. The method of claim 2, wherein an ion implantation for forming the first diffusion layer of the first general conductivity type is performed without performing a thermal diffusion for extending the buried diffusion layer of the first general conductivity type after the second epitaxial layer is formed.

4. The method of claim 2, further comprising forming a LOCOS oxide film in the second epitaxial layer, wherein ion implantation for forming the first diffusion layer of the first general conductivity type is performed through the LOCOS oxide film.

5. A method of manufacturing a semiconductor device, comprising:
providing a semiconductor substrate of a first general conductivity type;
forming a first buried diffusion layer of a second general conductivity type and a second buried diffusion layer of the second general conductivity type in the semiconductor substrate;
forming a first epitaxial layer of the second general conductivity type on the semiconductor substrate having the first and second buried diffusion layers therein;
implanting impurities of the first general conductivity type into a portion of the first epitaxial layer;
forming a second epitaxial layer of the second general conductivity type on the first epitaxial layer so as to form a buried diffusion layer of the first general conductivity type extending in the first and second epitaxial layers;
forming a first diffusion layer of the first general conductivity type in the second epitaxial layer so that the first diffusion layer of the first general conductivity type is in contact with the buried diffusion layer of the first general conductivity type;
forming a second diffusion layer of the first general conductivity type in the second epitaxial layer so as to operate as a back gate region;
forming a third diffusion layer of the first general conductivity type in the second epitaxial layer so as to operate as a base region;
forming a first diffusion layer of the second general conductivity type in the second epitaxial layer so as to operate as a collector region;
forming a second diffusion layer of the second general conductivity type in the third diffusion layer of the first general conductivity type so as to operate as an emitter region;
forming a third diffusion layer of the second general conductivity type in the second diffusion layer of the first general conductivity type so as to operate as a source region; and
forming a fourth diffusion layer of the second general conductivity type in the second diffusion layer of the first general conductivity type so as to operate as a drain region.

6. The method of claim 5, wherein the first diffusion layer of the first general conductivity type and the second diffusion layer of the first general conductivity type are formed in the same ion implantation step.

7. The method of claim 5, wherein an ion implantation for forming the first diffusion layer of the first general conductivity type is performed without performing a thermal diffusion for extending the buried diffusion layer of the first general conductivity type after the second epitaxial layer is formed.

8. The method of claim 5, further comprising forming a LOCOS oxide film in the second epitaxial layer, wherein ion implantation for forming the first diffusion layer of the first general conductivity type is performed through the LOCOS oxide film.
